(19) United States
(12) Patent Application Publication
(10) Pub. No.: US 2019/0311997 A1
(43) Pub. Date: Oct. 10, 2019

(54) SECURE ASSEMBLY OF DOCUMENTS OR MEDIA

(71) Applicant: GEMALTO SA, Meudon (FR)

(72) Inventors: Sébastien Gaspari, Gemenos (FR); Blandine Alleysson, Gemenos (FR); Christophe BOUSQUET, Gemenos (FR)

(73) Assignee: GEMALTO SA, Meudon (FR)

(21) Appl. No.: 16/466,825

(22) PCT Filed: Dec. 7, 2017
(86) PCT No.: PCT/EP2017/081907

§ 371 Date: Jun. 5, 2019

(30) Foreign Application Priority Data
Dec. 9, 2016 (EP) 16306653.3

(51) Int. Cl. H01L 23/00; H01L 23/498; H01L 23/66; G06K 19/077; C09J 9/00

(52) U.S. Cl. CPC H01L 23/573; H01L 24/29; H01L 23/49855; H01L 23/4985; H01L 23/66; H01L 2224/8385; G06K 19/0776; C09J 9/00; H01L 2223/6677; H01L 2224/29082; H01L 24/83

(57) ABSTRACT

The invention relates to a method for producing a security document, wherein a body is created that comprises two superimposed layers, a circuit which is electric and/or has an electronic chip arranged on the interface between the two layers, and a first adhesive between the two layers, which adheres to the two layers and/or the circuit. The method includes a step of depositing a second adhesive which is different from, or has a different behaviour from, the first adhesive in relation to the solvents or the temperature and partially adheres to at least one of the two layers and/or the circuit.

### FIELD OF THE INVENTION

The invention concerns security documents or media and their manufacturing process.

The invention concerns more particularly a security document comprising a security element in the form of an electronic circuit and another element in graphic form carried by a substrate, the whole being intimately linked mechanically and/or physically. The link is such that a fraudulent separation of one element from the whole leads to a deterioration of one and/or the other and dissuades a fraudster from using it later by associating it with another fraudulent security element.

It concerns in particular solutions where an antenna is intimately linked to a layer covering a smart document that may or may not support a photograph of the carrier.

Security documents are associated with secure applications. They include passports, identity cards, driving licences, access cards, health cards, prepaid telephone cards or bank cards, for example. Such documents are widely used and generally include a microchip module or a bare microchip that forms or connects a circuit.

When they include an electronic module, they can operate with and/or without contact depending on the application for which they are intended. They may be in the form of a card or booklet, for example. Such security documents are customized graphically and/or electrically with personal or entity-specific information (encryption key . . . ).

Personal information is the data of the document holder, such as for example his photo, name, date of birth, social security number, biometric information such as a fingerprint, validity date, etc. . . . . This personal information is printed on the surface of the document or on one or more sheets of the document when it is in booklet form. This information is usually also stored in a chip of the electronic module for comparison. Because of the high value associated with this personal information, these security documents are often targeted by criminals who copy, modify or forge them.

Common e-passport inlays (or electronic inserts) and/or an electronic passport cover layer use an adhesive to seal together two layers of plastic and/or paper material, between which there is a radio frequency communication (RFID) transponder. Fraud consists in removing the electronic circuit from the security document, in particular by delaminating the sheets that sandwich it, using a solvent or heat at high temperature. Since these adhesives are often sensitive to heat and/or solvent, it is therefore possible to remove the structure of the inlay by delaminating the sheets of the substrate through temperature and/or solvent to access the transponder without damaging it. As a result, this RF transponder can be reinserted into a fake passport that generally can have manipulated graphic data.

The objective of the invention is to ensure that if the above attack is carried out, the transponder and/or the document handled presents clear evidence of fraud, in particular by being visibly degraded or electronically non-functional, thus preventing it from being reinserted into a false medium or document.

The general purpose of the invention is to propose a solution to prevent criminal acts on security documents.

The invention concerns more particularly, but not exclusively, passport-type cards or booklets that have applications in identity control, access control, health and/or banking. The support can also be of any type with superimposed layers or sheets, such as a fabric, an object, furniture, clothing accessory, bracelet, any object obtained with 3D printing.

### PRIOR ART

Patent EP 1 646 972 B1 describes means of pairing a radiofrequency antenna with a contact and contactless (hybrid) smart card module. Electrical properties of the antenna are stored in the module chip, the antenna being intimately linked to a layer supporting a photograph of the holder. The chip only works if electrical properties stored in the chip match those measured during use.

The patent application WO2008119904 describes a security document comprising a fibrous inner layer with a security element, outer layers made of a transparent thermoplastic material, an RFID device housed within an insert layer. The document consists of two adhesive layers on either side of the fibrous layer and an adhesive layer between the insert layer (inlay) and an outer layer. At least two adhesive layers are of different natures. An adhesive layer may contain a cross-linking agent.

Patent application WO2006123065 describes an anti-counterfeiting adhesive label comprising a microcircuit attached to electrical contacts on a base layer and connected to an antenna, a separable layer of varnish printed on the base layer and interposed between the base layer and the antenna, at least one layer of external adhesive on the base layer for bonding the label to an object. The adhesion of a part of the separable layer and the adhesive strength of the outer adhesive are adapted so that the separable layer separates from the base layer causing damage to the antenna and/or the electrical circuit containing the microcircuit.

### Technical Problem

The purpose of the invention is therefore to remedy at least one of the disadvantages of the prior art. In particular, the invention aims to propose a process for the manufacture of a security document or medium equipped with the above means to prevent fraud. Preferably, the manufacturing process should be easy to implement and cost-effective.

### SUMMARY OF THE INVENTION

This invention preferably consists of applying at least two different types of glue/adhesive with different melting points and/or solvent sensitivities to assemble at least two layers of material enclosing an electronic/electrical circuit. A radio frequency transponder or electrical/electronic circuit is inserted between these two layers of material.

Preferably, at least one of these two layers partially covers the transponder or circuit so that any attempt to disassemble the assembly thus constituted causes a circuit breakage or damage to a layer of material and/or graphics, particularly in adjacent areas (point, line, surface) where a layer of adhesive of lower adhesive strength ends (due in particular to a fraudulent deactivation action of an assembly adhesive).

Preferably, the second layer of glue has a smaller surface area than the first. It can be applied by different means of coating (Dr Roller type), glue nozzle, coating, for example, this list not being exhaustive.

For this purpose, the invention concerns a process for the manufacture of a security document in which a body is made comprising two layers superimposed one on top of the other, an electrical and/or electronic chip circuit arranged at the interface between the said two layers, a first adhesive between the two layers and adhering to the two layers and/or to the circuit; the process is characterized in that it comprises a step of depositing a second adhesive different or having a different behaviour from the first to solvents or to temperature and adhering in part to at least one of the two layers and/or the circuit.

Thus, the invention makes it possible to surprise a fraudster during an attempt to disassemble the document and to cause a visible deterioration of the document (since the fraudster thinks a priori of a single adhesive used to manufacture the document).

According to other optional characteristics of the safety document:
The first and second adhesives differ in their melting temperature and/or sensitivity to solvents; preferably, the difference in melting temperature and/or sensitivity is large enough to surprise the fraudster. These melting temperatures may differ from 20 to 50° C. and/or their difference in the degree of sensitivity to solvents ranges from at least one to two, or at most, there is no common solvent for both adhesives; —At most, the difference in sensitivity to one given solvent may be very large between them, for example preferably more than two. Expressed as an absolute deviation, the difference in time required for the dissolution of the respective adhesives by the same solvent can preferably be more than 5 minutes.

Expressed relatively, the same solvent may preferably require at least twice as much time to dissolve or deactivate a first adhesive (or at least twice as much quantity) as the second adhesive; The relative difference in duration may be greater by a factor of 5 or 10 or 100.

For example, when using two polyurethane adhesives, one reactive and the other not, the first is dissolved by acetone after more than 10 hours while the second requires only a few minutes.
Adhesives 4, 5 can be placed at the interface separating the layers in complementary or separate or adjacent areas (Z1, Z2) on their thin edges;
Adhesives 4 and 5 may have a partial overlap of their respective areas (they may overlap or rest on each other);
The second adhesive is of greater resistance to temperature and/or to at least one solvent and is located in sensitive areas (Z2) located opposite the module and/or opposite at least one connection of the antenna to the module; Indeed, areas adjacent to the complementary areas or which overlap at least partially constitute singular weakening areas which are particularly exposed during disassembly because they allow damage to be generated more easily; The connection can be made by any known means, such as soldering, brazing, conductive glue, interpenetration; Thus, during a separation, the sensitive areas are more resistant to disassembly and facilitate a breakage of one of the elements constituting the assembly;
The second adhesive is of higher resistance to temperature and/or to at least one solvent and is located in sensitive areas (Z2) facing the module and/or facing at least one connection from the antenna to the module;
The second adhesive is of greater resistance to temperature and/or to a solvent than the first adhesive and is located in a central area (Z2), the first adhesive being placed around the second adhesive or bordering it on at least two sides,
At least one of the two layers of adhesive partially covers the transponder circuit so that any attack causes a break in the transponder circuit at the intersection of the transponder circuit and the two layers of glue;
At least one of the adhesives is arranged so as to have, in any direction at the interface between said material layers, at least one alternation of different adhesives or having different adhesion behaviours according to temperature and/or solvent;
At least one of the adhesives is randomly arranged and/or in the form of a spiral or zigzag cord or has an edge formed by broken or toothed line segments;
Adhesives can be identical at the origin but applied or activated differently. For example, a thermoplastic-based adhesive with a thermosetting phase can be activated differently at predetermined locations. Activation can be thermal or by radiation (UV, IR . . . ) or by distribution of activator or catalyst (for example on discontinuous layers of adhesives such as epoxy). Activation can be random or chosen and different from one “inlay” to another to increase the difficulty of disassembling a batch of security documents or media.

The invention shall also cover a security document obtained by the above process and shall take the form of a card or booklet.

### BRIEF DESCRIPTION OF THE FIGURES

Other advantages and characteristics of the invention will appear when reading the following description given as an illustrative and non-exhaustive example, with reference to the annexed drawings, wherein:

FIG. 1 illustrates a safety document in the course of manufacturing according to a first embodiment of the manufacturing process of the invention;

FIG. 2 illustrates a cross-sectional view of a security document (or insert) that can be obtained substantially according to the process of FIG. 1;

FIG. 3 illustrates a contactless card made according to a second embodiment of the process;

FIG. 4 illustrates the subject of FIG. 3 according to Section A-A;

FIG. 5 illustrates the subject of FIG. 4 enlarged with remarkable areas Z1-Z2 in the structure of the security document;

FIG. 6 schematically illustrates a behaviour of the structure of the security document during a fraudulent operation to separate the sheets 12 and 15 covering the electrical and/or electronic circuit.

### DESCRIPTION

A security document is any document, in particular in the form of a card or booklet, containing personal information of a person or entity. They are used in particular, but not exclusively, in passports, identity cards, driving licences, access cards, health cards, prepaid phone cards, bank cards and other applications.

Security documents may or may not include a radio frequency communication antenna 2. The examples described below refer to documents containing such an antenna 2. However, the invention is not limited to these cases and also applies to security documents that do not include an antenna. The transponder (2, 3) can be replaced by an electrical and/or electronic circuit 13 (not shown) (e.g. with fingerprint sensor, capacity, resistance, electrical contact or interconnection, wired or not capacitive plate . . . )

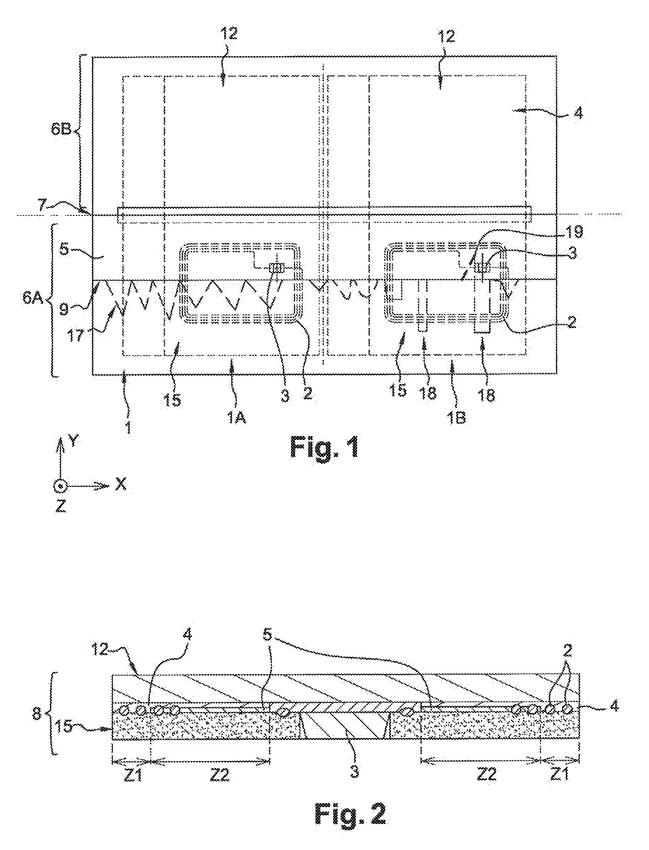

FIGS. 1 and 2 show a safety document 1 being manufactured according to a first embodiment of the manufacturing process of the invention. The process produces a “inlay” (or insert) body 8 comprising two layers of superimposed material, an electrical circuit 13 and/or an electronic chip 3 embedded between the layers, a first adhesive 4 adhering to the layers and/or the circuit.

In the example (FIG. 2), body 8 includes a sheet or layer 12 of passport cover (presented in a set of two). Layer 12 can be made of a plastic material, such as PVC (polyvinyl chloride), PLA (polylactic acid), PC (polycarbonate), PET or PETG (polyethylene terephthalate or glycolized polyethylene terephthalate), in a paper or synthetic material marketed under the brand name “Teslin”, or any other paper so-called “synthetic”, or textile.

This layer 12 is intended to be laminated and/or glued to at least one other layer of constitution 15. The assembly of layer 12 with at least one constitution (or covering) layer 15 is preferably direct, through adhesive(s) at their interface. In other words, a layer 15 adheres directly to another layer 12 through adhesive(s) only. The assembly is preferably free of an insert or inlay that would include an electronic circuit completely embedded in the insert or inlay to protect it completely. The circuit is located at the interface between the two layers 12, 15. The circuit includes portions that preferably adhere directly to one of layers 12 or 15. The circuit is preferably embedded directly in at least one of the two layers 12, 15 and/or in at least one of the two adhesives.

The assembly makes it possible to form (after cutting along the dotted line) a security document in the format of a card or booklet (in the case of a passport for example). In the case of a booklet, the assembly of the layers including antenna 2 can form an internal sheet or a cover of the booklet, especially a passport.

Here in the example, layer 15, in sheet form, is intended to receive another layer 12 in the form of a cover layer on top to sandwich the radio frequency transponder circuit 2, 3. In this case, a main support sheet 1 is arranged longitudinally in two sub-parts 6A and 6B separated by a central hinge 7.

A radio frequency antenna 2 (in batches of two) is made directly on one side of this main support sheet, in particular by inlaying conductive wires. This antenna 2 is in the form of a flat coil and operates at a frequency of 13.56 MHZ. It could have another form (notably dipole) and operate at another frequency, notably according to the UHF technology.

Antenna 2 is connected to a radio frequency module 3 detailed later in relation to FIG. 2.

On the main support sheet 15 and in its upper part 6B, it is planned to apply a first adhesive 4 intended to adhere to the layers and/or the electrical and/or electronic circuit 2, 3. The first adhesive covers all or part of the surface of the sheet 12.

This first adhesive 4 is of a first type chosen from those known from the prior art to the skilled person, including reactive or non-reactive polyurethane, pressure sensitive adhesive (PSA), hot-melt glue, acrylic glue, vinyl glue, epoxy glue . . . .

In this case, adhesive 4 has a melting temperature of between 100 and 120° C. and/or sensitive to a solvent such as water and/or has a low adhesion strength to layers 12 and 15, for example 20 to 30 N/cm².

According to a characteristic of a preferred embodiment of the invention, the process includes a step of depositing a second adhesive 5 between layers 12 and 15. In the example of FIG. 1, this second adhesive 5 is different from the first and is shaped and applied so as to adhere to a partial area of sheet (or layer) 15 and to the circuit. In this case, adhesive 5 has a rectangular strip shape with a width of about ⅖th of the width of the layer or sub-part 6A of the support sheet. The strip is arranged with a longitudinal edge adjacent to or aligned with the centre line 7 of the main support sheet 1 on sub-part 6A. The other edge 9 of the adhesive strip 5 is parallel to axis 7 and partially extends over circuit 13.

The adhesive is placed or partially placed on sub-part 12 or 6A of the support sheet 1 and on the circuit (antenna 2) and chip module 3, which is previously manufactured in the example. Alternatively, the circuit can be made partly on the adhesive 5 previously placed on sub-part 15, 6A of the support sheet 1.

Then, the two sub-parts 6A, 6B (or flaps) are folded together around axis 7 and laminated together in a known manner in order to be permanently joined. If necessary, the adhesives can be activated before folding and lamination pressing for example, by temperature, UV, IR radiation . . . .

According to a characteristic of this preferred embodiment, the first and second adhesives may differ in melting temperature and/or solvent sensitivity.

For example, first and second adhesives differ in melting temperature between 20 and 50° C. Alternatively or preferably in addition, these adhesives may also have no common solvent to better prevent malicious disassembly.

In the case of a juxtaposed application of EVA (ethylene vinyl acetate) and reactive polyurethane adhesives, an aqueous solvent will only dissolve the EVA, leaving the polyurethane adhesive intact. Similarly, the use of a UV cross-linking glue and a solvent-based glue in juxtaposed or superimposed application will result in reacting to different solvents.

According to one characteristic, the adhesives are arranged at the interface separating the layers or sheets and partly overlap. In FIG. 1, the overlap area of both adhesives 4 and 5 is adjacent to axis 7 and extends in width over a distance corresponding to the width of adhesive 5.

Alternatively, adhesives can be placed in complementary areas that do not overlap after layers 12 and 15 have been superimposed. The deposition can be carried out precisely, in particular by screen printing or material jet printing. There may be a gap between non-overlapping adhesives to accentuate a transition when separating layers or sheets 12 and 15.

Alternatively, the interface lines between the first and second layers 12, 15 include, in any direction in a plane of the document, a succession of different adhesives or different adhesions in predetermined or random areas; for example, the sheet structure may include one or more adhesive-free areas (for example, the adhesion can be achieved by the very nature of the layer (polyurethane, thermally activated adhesive, polycarbonate . . . ). The structure can include a weak adhesion area of the layers between each other followed by a strong adhesion area at any point in the circuit.

In both embodiments, the adhesives are preferably arranged so that the antenna path and/or connection areas from the module to the antenna undergo a transition of adhesives along their path or extent, parallel to the main plane of the document or card. Thus, the antenna can travel along its path through an environment of a first adhesive and then undergo an environmental transition to an environment of the second adhesive.

Alternatively, a first connection of the module to the antenna can be embedded by an adhesive while a second connection is embedded in another adhesive different from the first.

In general, rather than being different in nature, adhesives should behave differently from each other depending on how they have been applied or conditioned, or activated.

When a fraudster attempts to soften adhesive 4, he can remove sheet 12 with the adhesive from sub-part 15 or 6A and only the lower part of the antenna embedded in adhesive 4 and outside adhesive 5. When the separation force reaches the interface between the two adhesives, the antenna is retained by the second adhesive on the support 12. If the separation force of the sheets is greater than, for example, about two newtons, the antenna breaks at the boundary 9 or interface 16 between the two adhesives 4 and 5.

Alternatively, the antenna may travel along its path through an environment of first and second adhesives facing the antenna (e. g. placed on the same side of the antenna) and then undergo an environmental transition to an environment consisting solely of a second adhesive ensuring the adhesion of the two sub-parts.

According to one characteristic, the adhesive with higher resistance to temperature and/or to at least one solvent is arranged at an interface separating the layers in remarkable sensitive areas such as those located opposite the module and/or a connection from the antenna to the module.

Thus, when the layers are separated by a first adhesive of low strength or adhesion power, the adhesion remains stronger by the second adhesive of higher strength or adhesion power. Any traction pursued to separate sheets 12 and 15 necessarily leads to a break of the circuit.

Thus, this lack of relative adhesion increases the rate of separation of the layers locally before strongly resisting and facilitates circuit failure or tearing of one of the two layers.

For example, the first adhesive will require a separation force of 3 to 6 N/cm² while the second adhesive will require a separation force of 20 to 30 N/cm², which will lead to a decrease in the rate of layer separation and a breakage of the antenna wire.

According to one characteristic, the adhesive with the highest temperature and/or solvent resistance is placed at the interface of the layers in a central area; the adhesive with the lowest temperature and/or solvent resistance is placed around the first adhesive or borders the first adhesive on at least two sides.

For example, a complex composed of a UV glue in the central zone and a solvent-based glue on either side of this central zone will react differently to a solvent attack in the two application zones.

According to one characteristic, at least one of these two layers will partially cover the transponder so that any attack causes the transponder to break at the intersection of the circuit with the two layers of glue.

According to another general alternative, also illustrated in FIG. 1 (dotted line), the different embodiments of the process are characterized in that at least one of the adhesives 12, 15 is arranged in such a way that the structure of the document (or card) presents in any direction, at the interface between the said material layers, at least one alternation of different adhesives (whose function is to assemble the layers together) or having different adhesion behaviours according to temperature and/or solvent. The alternation of adhesives preferably follows an irregular broken line 17 rather than a straight line 9 so that a hacker/fraudster cannot anticipate their separation location.

Thus, for example, in a direction X parallel to the edge 9 in the plane X, Y of the mark XYZ, parallel to the main plane of document X, Y, there is an alternation of two adhesives 4 and 5 (especially at the adhesive teeth 18) which will behave differently at separation forces due to different dissolution and/or fusion rates.

Advantageously, at least one of the adhesives 4, 5 is randomly arranged and/or in the form of a spiral or zigzag cord or has an edge formed by broken or toothed line segments 17, 18. For example, the invention provides for the application of a bead of second adhesive to a substrate by dispensing a nozzle that oscillates transversely with respect to a direction of movement of the substrate.

Alternatively, an adhesive film 4 or 5 can be applied to the substrate 12 or 15 and a fringe or random portion of the film can be removed or eliminated by any known means (laser, pre-cutting, cutting, etc.). Adhesives can also be applied by spraying or printing using a mask that defines a predetermined or random shape.

In FIG. 2, a body of a card or passport inlay can be obtained substantially as explained in reference to FIG. 1. It differs, however, in that adhesive 5 is substantially centred on the module or chip 3. Adhesive 5 overlaps (or extends over) a part of the radio frequency electrical circuit, in particular coils 2, and adheres to layer or sheet 15. An electronic module is placed in a cavity on sheet 15 and connected to antenna ends 2.

Adhesive 4, different from adhesive 5, covers almost the entire electrical circuit. It overlaps adhesive 5, part of the coils 2 already covered by adhesive 5 and part of the coils not covered by adhesive 5.

When attempting to separate sheets 12 and 15, the circuit can more easily break at the interface between Z1 and Z2, corresponding to a transition (or difference) in the adhesion of the turns to sheets 12 and 15.

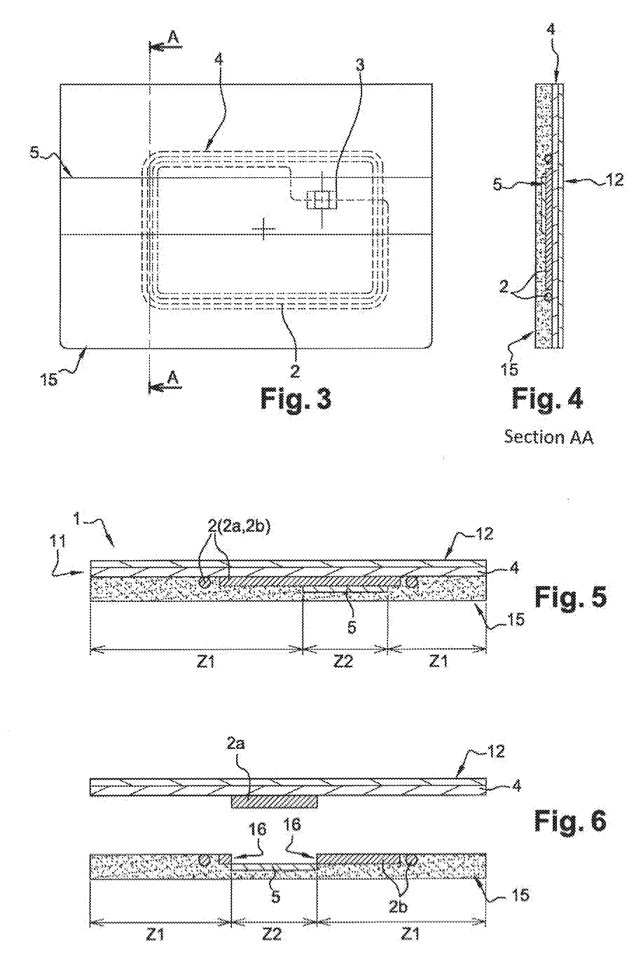

FIGS. 3 to 4 illustrate a contactless card made according to a second embodiment of the process. The card consists of a support sheet 15 in “Teslin” or plastic sheet and a plastic sheet 12 in a cover layer, the two layers of glue 4 and 5 as well as the transponder comprising a module 3 with a chip connected to the antenna 2

Glue 5 has a reduced area or surface area and is first applied to the support sheet 1 in an area Z2, then the antenna 2 is embedded or deposited on sheet 15 in an area Z1 and partly in the area Z2 on the glue layer 5 including, for example, a portion of the short lateral sides of the antenna.

Then, a layer of glue 4 is preferably applied to the support sheet 15 over glue 5 and part of the transponder 2, 3;

Finally, the other cover layer 12 is placed on top of the above assembly to cover it completely. The assembly consisting of the lower support sheet 15, the reduced surface area with glue 5, the transponder 2.3, the glue 4 and the sheet 12 superimposed in this order is heat-laminated, for example.

If necessary, the antenna may be weakly embedded in the support sheet 15 as long as the latter has a thermally activated adhesive coating to fix the antenna. On the other hand, the antenna can be more strongly embedded in the glue layer 5 with a reduced surface area.

FIG. 5 shows the subject of FIG. 4 indicating the remarkable zones Z1 and Z2 in the structure of the safety document;

FIG. 6 shows a separation of the support sheets 12 and 15 and the fracture of the antenna 2 into two parts 2a and 2b at the interfaces of adhesives 4 and 5

For example, since adhesive 4 is stronger than adhesive 5, part 2a of antenna 2 (in zone Z2), adheres more to sheet 12 via adhesive 4 than it adheres to sheet 15 via adhesive 5; therefore, when sheets 12 and 15 are separated, part 2a breaks at the interface of zone Z1 and Z2. One part 2a is teared off by sheet 12 while the other part 2b remains attached to sheet 15.

If necessary, lamination is carried out after encrustation of the antenna wire on support 1 and on the reduced glue layer 5. Lamination is preferably limited to the area covered by glue 5.

This has the effect of driving the turns or tracks of the antenna into the support sheet 15 and making them adhere well to this support sheet in the area of the adhesive 5. On the contrary, the turns or tracks of the antenna located outside the glue layer 5 are less embedded in the support sheet 1 and/or the adhesive 5 due to the thickness of the adhesive 5.

If the temperature of the assembly is raised by a fraudster, glue 4 softens first, it is possible to detach sheet 12 from sheet 15 by taking with it a part of the antenna that still adheres to glue 4.

However, glue 5 has not yet reached its melting temperature and maintains adhesion to the other sheet 15 and to a complementary part of the transponder antenna. If a separation force of sheets 12, 15 is continued, a break occurs at the interface (line 9 or 17) separating the areas where the two adhesives extend because one part of the antenna is pulled by sheet 12 and the other part of the antenna is retained by sheet 15 and the adhesive 5.

When antenna 2 is made by encrusting a metal wire in the first layer 15, a sonotrode is preferably used which, when subjected to ultrasonic waves, restores the resulting vibratory energy in the wire to be encrusted.

Another step in the document manufacturing process may also be to provide a reception cavity 14 in layer 12 to insert an electronic module 13 and connect it electrically to antenna 2. This cavity can be made before or after the antenna is made. The connection of the electronic module 3 to the ends of the antenna wire is then carried out by a thermo-compression process known to the person skilled in the art.

In all embodiments, the shape of the extent of the adhesives, particularly the adhesive with a reduced surface area, can be any or random as shown in FIG. 1. In particular, adhesive 4 may have at least one side formed by broken lines or teeth 17, 18 (shown as dotted lines) or zigzag or star-shaped instead of the straight lower limit 9 in order to avoid predicting the limit of one of the adhesives from the outside. For example, adhesive 4 may have irregular projections or tongues 18 extending towards the circuit.

Alternatively, adhesive 5 may have an area 19 free of adhesion or adhesive and extending over a part of the circuit to cause disparities in adhesion and complicate a fraudster's task.

Adhesive 5 can have a temperature resistance above 120° C. and/or can be soluble only in a solvent (e.g. acetone) and/or have a strong adhesion to substrates (Teslin™ or paper cover layer).

1. Process of manufacturing a security document in which a body is produced comprising two superimposed layers, an electrical circuit and/or electronic chip arranged at the interface between said two layers, a first adhesive between said two layers and adhering to the two layers and/or the circuit,
wherein the process comprises a step of depositing a second adhesive different or having a different behaviour from the first adhesive relative to solvents or temperature and adhering in part to at least one of the two layers and/or to the circuit.

2. Process according to claim 1, wherein the first and second adhesives differ in melting temperature and/or solvent sensitivity.

3. Process according to claim 2, wherein said melting temperatures differ from 20 to 50° C. and/or their difference in degree of sensitivity to solvents is at least twice as great or there is no solvent common to both adhesives.

4. Process according to claim 1, wherein the adhesives partially overlap or are arranged at the interface separating the layers in complementary areas.

5. Process according to claim 4, wherein the second adhesive is of higher resistance to temperature and/or at least one solvent and is located in sensitive areas facing the module and/or facing at least one connection of the antenna to the module.

6. Process according to claim 4, wherein said second adhesive is of higher temperature resistance and/or solvent resistance than the first adhesive and is located in a central region and wherein the first adhesive is placed around the second adhesive or borders the second adhesive on at least two sides.

7. Process according to claim 1, wherein at least one of the two layers partially covers a transponder circuit so that any attack causes a break in the transponder circuit at the intersection of the transponder circuit with the two adhesive layers.

8. Process according to claim 1, wherein at least one of the adhesives is arranged so as to have, in any direction at the interface between said material layers, at least one alternation of different adhesives or having different adhesion behaviours according to temperature and/or solvent.

9. Process according to claim 1, wherein at least one of the adhesives is randomly arranged and/or in the form of a spiral or zigzag cord or has an edge formed by broken or serrated line segments.

10. A security document obtained by the process according to claim 1, wherein it is in the form of a smart card or booklet.
